(19) United States
(12) Patent Application Publication
(10) Pub. No.: US 2017/0211174 A1
(43) Pub. Date: Jul. 27, 2017

(54) TRIBOLOGICAL SYSTEM WITH REDUCED COUNTER BODY WEAR

(71) Applicant: OERLIKON SURFACE SOLUTIONS AG, PFÄFFIKON, Pfäffikon SZ (CH)

(72) Inventors: Juergen Ramm, Maienfeld (CH); Florian Seibert, Sevelen (CH); Beno Widrig, Bad Ragaz (CH)

(21) Appl. No.: 15/302,564

(22) PCT Filed: Apr. 9, 2015
(86) PCT No.: PCT/EP2015/057684

§ 371 Date: Nov. 3, 2016

Related U.S. Application Data
(60) Provisional application No. 61/977,188, filed on Apr. 9, 2014.

(51) Int. Cl. C23C 14/32; C23C 16/50; C23C 16/34; C23C 14/06

(52) U.S. Cl. CPC C23C 14/325; C23C 14/0641; C23C 16/50; C23C 16/34

(57) ABSTRACT

A tribological system with a substantially improved tribological behaviour, which includes a body with a first contact face, which is coated at least partially with a first coating, a counter body with a second contact face, which is coated at least partially with a second coating and a lubricant as an interbedding. The first and second coating each include a layer as an outermost layer, wherein the composition of the outermost layer of the first coating and the composition of the outermost layer of the second coating are selected as such, that both outermost layers are smeared on steel surfaces when they are exposed to a tribological contact with steel, and both outermost layers are material-related layers, so that the element composition of the fist outermost layer complies to the element composition of the second outermost layer at least to 60 atom percent.

The current invention relates to a tribological system with significantly improved tribological behaviour and reduced wear of the counter body according to claim 1.

The optimization of the tribological behaviour is an essential goal in the design of tools and components that are used in machines, combustion engines and gear boxes. In numerous cases, one partner (in the following referred to as “tribological body” or simply as “body”) of the tribological system is provided with a layer. With this coating, various goals are pursued. Especially the wear of the body is to be reduced, for example of a cutting tool. That is especially true for tool applications, but is also important for components. Often in tribological systems, in which two components are in tribological contact, not only the wear of the one partner i.e. the body is to be reduced, but additionally the wear of the other partner in the tribological contact (in the following referred to as “counter body”) is to be reduced. In many component applications, e.g. in the area of engines, finally the friction coefficient in the tribological system is to be reduced, which is a requirement for reducing the wear in the tribocontact (tribocontact =tribological contact). The use of coatings for such applications is proven since decades and both tool coatings as well as component coatings are applied industrially.

The coating of the tools and components is carried out in many cases by means of Physical Vapour Deposition (PVD) technology or the Plasma Enhanced Chemical Vapour Deposition (PECVD) technology. Coating processes such as sputtering, cathodic arc evaporation and plasma supported CVD resp. combinations of these processes belong to the state of the art. The process of the cathodic arc evaporation finds its application particularly in the area of tool coating of cutting-, stamping- and forming tools. To a lesser extent it is also used for component coating, for example for the coating of piston rings with chromium nitride (CrN). This coating process is robust and reliable and a broad spectrum of coating materials can be synthesised therewith. The disadvantage of this process are splashes, which arise during the evaporation process of the cathode material and partially are embedded in the coating as so called droplets. This increases their surface roughness and it makes it necessary, that these coatings must be post-treated for applications, in which low friction coefficients are required. In the applications of CrN layers on piston rings the usual coating thickness is between 30 μm and 50 μm. Approximately 3 to 5 μm are removed by the post-treatment in order to achieve the required surface roughness of the layer surface. If the post-treatment is not carried out, on the one hand there is the danger that with the top roughness of the CrN-coating (characterized by the Rpk and Rpkx values) the counter body is worn very heavily and additionally breaking out of splashes or coating particles can occur, they additionally wear the counter body faster by means of “emery effect” as they have a greater hardness than the counter body. However, the mentioned post-treatment steps for smoothing the applied layers are standard procedures and introduced since long in the mass production. Here, not a specific type of post-treatment will be addressed, but the term shall include all kinds of improvements of the surface roughness, such as for example polishing, lapping, brushing, grinding etc.

### Problem

Of course it would be advantageous to dispense with a post-treatment, which, at the current state of the art, is only possible for selected coating methods and only for a few carbon-based materials. However, with the post-treatment and the improvement of the layer surface, not all problems are solved. In many cases, occasionally the coated bodies are briefly operated in lubrication deficiency, as it is for example also the case for piston rings. It is therefore an important requirement for such tribological systems that they don't completely fail during lubrication deficiency, i.e. that there is no destruction of the layer nor a destruction of the counter body. As the layer material is selected to be harder than the counter body material in its mechanical properties, there is the danger that the counter body material is transferred to or smeared-on the coating material during lubrication deficiency. For the examination of such tribological systems, where the behaviour of body and counter body is examined, the reciprocating wear test (SRV test, germ. “Schwingungs-Reib-Verschleisstest) has been developed. In the following, according to this test, the problem of smearing-on shall be clarified and the inventive results shall be explained. All measurements in the SRV test have been carried out with the same parameters regarding frequency, glideslope, test load and test temperature, so that all test results are comparable.

For the tests, bodies have been coated with the process of the reactive cathodic arc evaporation with different materials. Polished discs (Ø22 mm×5.6 mm) from steel (90MnCrV8, 1.2842) have been used as bodies having a Rockwell hardness >62 HRC and having a surface roughness Ra≦0.05 μm. Steel balls from 100Cr6 (hardened steel, 60-68 HRC, Ø10 mm) have been used as counter bodies. The mechanical properties of the layer materials to be compared have been determined by means of the process of nanoindentation and are compiled in table 1. For the person skilled in the art it is understood that these values can be changed as well by modifications to the coating process and they are only mentioned here in order to indicate typical relationships in scale and for being able to better understand the results from the SRV tests. The SRV tests have been carried out for different conditions on CrN, molybdenum nitride (MoN) and molybdenum copper nitride (MoCuN):

A. Dry [A1] (i.e. without lubrication such as oil) or lubricated [A2] (in the present trials always with a diesel oil as lubricant)

B. Coated body+uncoated counter body [B1] or coated body+coated counter body [B2]

C. With post-treatment of the coating [C1] or without post-treatment of the coating [C2]

TABLE 1
Mechanical properties of the layers used for the SRV tests

| | CrN | MoN | MoCuN |
|---|---|---|---|
| Indentations hardness | 15 | 33 | 23 |
| [GPa] | | | |
| Modulus of elasticity | 316 | 380 | 260 |
| [Gpa] | | | |

1. SRV test: dry, coated body and uncoated counter body, without post-treatment of the layer

In FIG. 1, the graphs of the friction coefficients over time obtained in the SRV test for the CrN, MoN and MoCuN coated bodies are shown, which have been obtained in the contact with the polished steel ball, without the use of a lubricant and without the post-treatment of the layer. The friction coefficient of CrN (1) lies in the range between 0.7 and 0.8 and is thus the largest among the investigated layers. In the beginning also MoCuN (3) shows a friction coefficient of 0.7, which after a short time falls down to 0.6 and below. This graph is characterized by high noise. MoN (2) starts with the smallest friction coefficient of 0.5, which approaches the one of MoCuN at the end of the test, which lies in the range between 0.5 and 0.6. In the graph progression there are some “outbreaks” that can be explained with brief smearing-on of the counter body material. It seems that this smearing-on is dissolving again every time. The larger “noise” in the graph of MoCuN that occurs after approximately 10 min, is attributed to the fact that this coating comprises a larger number of especially larger splashes. The reason is that the MoCu targets, which are used a cathode for the arc evaporation usually show a higher tendency for splash generation in comparison to the pure Mo targets. These splashes can be found partially in the deposited layer.

FIG. 2 shows the recordings that have been made after the SRV test with the light microscope that characterize the wear traces on the layers (a-c) and the corresponding wear of the counter bodies (d-f). The upper row in the table illustrates the wear of the layer in the friction track. Thus it can be seen that with CrN (a) (also demonstrated through an EDX analysis) a smearing-on of the counter body material (100Cr6) on the layer surface occurs, while such a smearing-on with MoN (b) and MoCuN (c) layer cannot be detected. The wear of the counter body is shown in the lower row of FIG. 2. The diameter of the wear cap, the part of the uncoated counter body that has been worn during the SRV test, is the largest in the case of the CrN coated body (d). For MoN (e) one finds the slightest wear. In this case a partial transfer takes place from the Mo-containing layer material to the counter body (dark colorizing of the wear cap). MoCuN (f) takes a middle position with respect to wear, but also shows the Mo- and Cu-containing transfer on the counter body. This smearing-on of the counter body seems to be an essential reason that there is no material transfer to the layer.

In summary, it can be said that in contrast to the CrN coatings, there is no smearing of the counter body material onto the layer with MoN layers, although the layers haven't been post treated and no lubricant has been used. The reason therefore is that the counter body, is smeared-on by a Mo-containing layer at least partially. In comparison with CrN one can conclude that the smearing-on of the counter body is of greater importance for its wear reduction than an adaption to its hardness. An adaption to the coating hardness is carried out for example in the case of CrN such as the coating hardness is reduced for steel counter bodies, which can be realized by modifying the coating parameters. The smaller coating hardness leads to less wear of the counter body in the case of lubrication deficiency, but of course, on the other hand poses the danger of the larger layer wear.

It should also be noted that some carbonaceous layers, by sacrificing a part of its own layer materials, can smear graphitic carbon onto the counter body. However, at high surface pressures, these layer systems fail, which is probably due to the fact that the smearing-on of the counter body has no good adhesion and in addition the “sacrificing” of the layer at higher temperatures cannot be controlled and takes place too fast. Additionally the reliability of this carbon smearing in the smeared-on contact strongly depends on the lubricant.

For the sake of completeness and without any results being shown in detail, it is stated that the post-treatment of the layer doesn't bring substantial improvements under these dry test conditions, neither for the reduction of the layer wear nor for the counter body wear. A polishing of the layer reduces this problem somewhat, because the running-in behaviour takes place at lower friction coefficients though it doesn't solve it, because mostly after a short friction contact the smearing-on of the counter body material on the layer starts anew, especially when the coating material doesn't smear-onto the counter body.

2. SRV test: lubricated, coated body and uncoated counter body, without post-treatment of the layer

In further trials the lubricated conditions for the above case have been investigated. The tests have been carried out with a coated body without post-treatment and an uncoated polished counter body. A standard diesel oil has been used as lubricant. Trials with other oils have been carried out, which qualitatively provided the same results, although, for example the friction coefficient of a 0W20 Mo-DTC oil being significantly smaller than that of diesel oil. The friction coefficients identified with the diesel oil are shown in FIG. 3. They are significantly smaller under lubricated conditions and are allocated altogether in a narrow band between approximately 0.15 and 0.2. While the friction coefficient of CrN after the running-in is more or less stable, one can detect a small steady decrease of the friction coefficient for MoN and MoCuN. The corresponding wear images are shown in FIG. 4. Wear of the layer can hardly be detected. Essentially a smoothening of the layer occurs. Presumably, single splashes that are not carried away through a forced lubricant transport in these simplified test conditions, lead to minim scratch marks on the layer. In contrast, the wear of the uncoated counter body is clearly visible. In this test the wear cap diameter for MoN is the largest, which might be, because this material also comprises the biggest hardness. There is no significant difference between CrN and MoCuN. In summary, one can say that in comparison to dry test conditions the additional lubricant contributes to a strong reduction of the friction coefficient and the coating wear and that there is no material transmission from the counter body to the layer in all cases, as it has been observed under dry conditions for CrN. The counter body wear gets less in comparison to the dry conditions, but stays striking and is the largest for the hardest of the coatings, namely MoN.

3. SRV test: Comparative investigations on MoN coatings

Firstly, the results for the MoN coatings shall be shown, which result from the lubricated case, the coated body with a post-treatment of the coating, and the uncoated polished counter body. These are conditions as they are used today in the state of the art technology for tribological systems and which lead to good results. Therefore, they shall serve as benchmark, in order to be able to better assess the inventive step, which follows later. For this conditions, with use of diesel oil as lubricant, one gets the graph for the friction coefficient (1) from FIG. 5 that finally stabilizes at a value of 0.2. Here, it is mentioned again that the friction coefficient is significantly dependant from each particular lubricant and lies, for example, for otherwise equal test conditions, with a 0W20 Mo-DTC oil under equal conditions at 0.07. Additionally, two further graphs of friction coefficients over time are shown in FIG. 5. Graph (2) shows the progress for dry conditions, for the post-treated coated body and the uncoated polished counter body. The friction coefficient at the end of the tests is between 0.5 and 0.6 in wide areas of the graph, thus is not very much different from the one that results from the layer without post-treatment (compare FIG. 1). However, at the end of the graph it suddenly rises and then falls again. Brief smearing-on of the counter body material could be the reason therefore. Additionally, the progress of the friction coefficient that results from dry conditions, coated body and coated counter body, but without post-treated layers (3) on both sides has been incorporated in the figure. Surprisingly this graph mostly runs below (2) and also terminates significantly below this graph. The wear of the MoN layers and the corresponding counter bodies are shown in FIG. 6. For (1) no wear of the layer can be detected. There is also no wear on the counter body. The markings on the coating and the counter body originate from the decoration of the lubricant and the diameter in the decoration of the counter body originates solely from its elastic deformation in the Hertzian contact. This is a typical result for a desired tribological contact and is the goal of the optimization of a tribological contact using coatings. Graph (2) shows barely any wear of the layer (colouring is again a decoration through the oil). However, the counter body has a significant wear which barely differs from case A1/B1/C2 in FIG. 1. For graph (3) the curve of the friction coefficient over time shows an interesting behaviour. If one compares (1) with (3) of FIG. 5, one can see in the progress of the latter, after a certain time, a continuous decrease of the friction coefficient from the region between 0.5 and 0.6 to a value of around 0.4. This effect could be explained as a sort of self-smoothing. The friction coefficient of 0.4 is still too big for the most applications. But the indication of a self-smoothing effect with similar, not post-treated coatings for body and counter body was still surprising.

For this reason, trials have been carried out, at which both the body as well as the counter body have been coated and in fact with the same layer material. After the coating neither the coated body nor the coated counter body have been post-treated. In FIG. 7 the measured friction coefficients are shown as a function of time. The CrN system is running-in with the lowest friction coefficient of 0.4 and rises during the test to values between 0.4 and 0.5. MoCuN starts at a friction coefficient of around 0.5 and falls after a view minutes to around the value of CrN. The friction coefficient of MoN (this graph has already been shown in FIG. 5), as hardest coating, initially has a value between 0.5 and 0.6 and then falls at the end of the test also to a value between 0.4 and 0.5. In FIG. 8 the corresponding wear images are shown. In comparison to an uncoated and polished counter body (FIG. 2), the coating of the counter body leads in all cases to a significantly smaller diameter of the wear cap and therefore to a smaller counter body wear. With respect to this almost no difference can be detected between CrN and MoN. Even with MoCuN, the wear cap diameter is insignificantly larger. Here, the increased depositions at the edges of the wear track are noticeable, which are caused by the larger splash density, which occurs with the cathodic arc evaporation of MoCu. At the end of the tests, the friction coefficients lie close to each other. Smearing doesn't occur under these conditions.

The previous results can be summarized as follows:
At dry running (applies mutatis mutandis also to lubrication deficiency, although less strong), the uncoated 100Cr6 counter body is worn, both with and without post-treatment of the layer. With many layer systems (here only CrN is shown as an example, but this is also valid for almost all Al-containing layers such as AlCrN, AlCrO, TiAlN and also for less hard nitride layers such as TiN, ZrN, NbN) there is a material transfer from the counter body to the harder layer in the case of a softer counter body.
The MoN-based layers also wear the counter body under these conditions, but there is no material transfer from the counter body to the layer. The reason therefore is that the MoN-based layers are smearing-on the counter body with a Mo-containing layer.
Without post-treatment of the layer, the uncoated counter body is also worn under lubricated conditions, although the friction coefficient being low.
A coating not only of the body, but additionally also of the counter body, for dry conditions, significantly reduces both the friction coefficient of the tribological system as well as the wear of the counter body. The effect of smearing-on doesn't happen.

From the described, the following problems to be solved can be derived:
Many tribological systems, in which only the body is coated (e.g. CrN), fail even if they only run short-term under deficient lubrication or dry friction conditions. Possible causes can be an insufficient or short-term interrupted lubrication supply or a short-term high contact pressure of the friction partners, which pushes the lubricant away from the contact surface more than expected. As a result thereof, and because the coating material in most cases has the better mechanical and thermal properties, one can detect a smearing-on of the counter body onto the coated body. The smearing-on of the counter body material can lead to jamming in the tribological system and to partial or total blockade. Therefore jamming must be prevented. It is therefore the most important goal of the invention to prevent or to reduce the wear of the counter body in contact with a coated body, in the case the tribological systems runs into a lubrication deficiency.
Layers, that are produced by means of cathodic arc evaporation (but usually also other PVD coatings such as for example the one produced by sputtering) and which have to satisfy the requirements of tribological applications, usually have to be post-treated, in order to reduce their surface roughness and therefore the wear of the counter body. Post-treatment requires a big effort depending on the substrate geometry and additionally an optimal post-treatment should also match the counter body (e.g. surface quality). Therefore it is a further goal of the invention that a post-treatment of the coated parts that are foreseen for the use under lubricated conditions, is no longer required.
A free selection of a counter body material that is mechanically adapted to the layer doesn't exist in most cases. Reasons therefore are high material costs, availability of such a material or because processing such a material is too difficult and expensive. This limitation shall be resolved.

### Description of the Inventive Solution

The described problem is solved by means of a coating not only of the body, but additionally also of the counter body, wherein the coating of the body and the counter body essentially comprise the same material-related layers on their surfaces.

The layers are selected as such that the in essence kind-related coatings of body and counter body under the addition of a lubricant smooth themselves, without a post-treatment being required for any of the layers.

In the context of the current invention, material-related coatings are layers that comprise an element composition that is not absolutely equal, but complies to at least to 60 atom percent.

This means that a first layer or a first coating and a second layer or a second coating are material-related layers or material-related coatings, when the element composition of the first layer or coating complies to at least 60 atom percent to the second layer or coating.

A further condition for solving the problem is the property of the layer material to at least partially smear on the counter body.

A further condition for solving the problem is the property of the layer material that the splashes present in the layer or its surface (also named droplets) are not strongly compounded with the layer that means they are easily removable which can be demonstrated for example by means of a post-treatment and a determination of the surface quality, wherein Rpk and Rpkx are smaller than Rvk and Rvkx after the post-treatment.

The solution is based on a coating comprising Mo or MoN comprising a MoN-based layer material that can comprise additional dopants of other elements.

The coating of the body and the counter body is realized by means of a PVD process or a PECVD process or a combination of these processes. The preferred process for the coating is the reactive cathodic arc evaporation. In this process, the cathode (=target) from Mo or an alloy from Mo and one (or more) corresponding dopant element(s) is evaporated by means of cathodic arcs in the vacuum and the corresponding reactive gas is added to the process by means of a gas flow controller. Either the addition of the reactive gas is controlled by means of the gas flow or the total pressure. The process is well known by the person skilled in the art and is used for many years for coatings on an industrial scale. Of course the dopants can be introduced in the coating through a further target from the dopant material or by means of addition of gases. In the latter case the corresponding gas of the arc discharge or another gas discharge is supplied by means of a controllable gas inlet and is decomposed or stimulated fully or partially in the plasma of the arc discharge or another auxiliary plasma. In this manner, for example, MoN or MoCuN (meaning MoN layers with Cu dopants) can be produced. The roughness of the layer surface is characteristic for layers that have been produced by arc evaporation which is primarily caused by macro particles (or splashes) that are created during the arc evaporation, but can also be created by evaporation for example by means of sputtering. However, the roughness increase in/on the layer by means of these splashes is especially significant with arc evaporation. A post-treatment, for example by means of polishing or brushing or micro blasting doesn't show a significant reduction of the roughness by all layers that have been produced by means of arc evaporation. This is due to the fact that the introduction of splashes in the layer is differently stable, which is the reason why the layers can be post-treated more or less efficiently. However, in case of the MoN-based layers, the post-treatment works well, both for the pure MoN layers as well as for the layers with dopants. This is shown in FIG. 9, in which the roughness of more or less equally thick MoN layers is compared to the roughness of layers with MoCuN before and after the post-treatment (here for example by means of brushing, but this shall not be understood as limitation to this process). The initial roughness of the polished steel substrate for the thests was Rz=0.2 μm and Ra=0.02 μm. That means that by means of the coating the initial roughness of the uncoated polished substrate has been increased significantly. Dependant on the kind of coating, the increase of the roughness can be different, as prove the values in the figure for a MoN (black) and a MoCuN (gray) layer. Two layers are compared in the figure that comprise about the same layer thickness of 2 μm. However, the experience also shows that the layer roughness with the arc coating is not only dependant on the coating material, but increases also together with the layer thickness, as the number of splashes that impinge on the surface accumulates. A post-treatment of the layers should either remove the splashes from the layer surface or the splashes should let themselves be smoothed easily. The data in FIG. 9 verify that this applies to MoN and MoCuN layers. In the figure the roughness parameters of the layers before the post-treatment are shown in the left quadrant and the ones of the post-treatment in the right one. In comparison, on the one hand one can see that the post-treatment comprises a significant effect. This can be recognized especially with the top roughness Rpk and Rpkx next to the significant reduction of the Rz and Ra values. It is also astonishing that post-treated MoN and MoCuN layers hardly differ from one another with respect to their roughness values. This has been completely different before the post-treatment. Rz and Ra values for MoN and MoCuN have been significantly different from one another, wherein MoCuN exhibited about twice as large values as MoN. Even more significant were the differences in the Rpk and Rpkx values before the post-treatment and again insignificantly small after the post-treatment. One can also see a significant reduction for the Rvk and Rvkx values after the post-treatment, however the difference between the two layers remains more significant compared to the other roughness parameters.

The investigations in FIG. 9 have been carried out on substrates that had a well-polished substrate surface before the coating. It is obvious that there aren't such well-polished surfaces for many applications and that these cannot be produced or can only be produced with a large economical effort. Therefore also “technical surfaces” have been investigated, whose roughness values lie in the range of the layer roughness or even above. Measurements of typical surfaces of valve shafts before and after the coating have been compiled in table 2. 1.33 μm has been identified as Rpkx value on the valve shaft. The post-treatment of the valve shaft has been realized by means of brushing and afterwards a roughness measurement has been carried out again. Through this, the Rpkx value was reduced to about 25% of the initial value, meaning that through the combination of the coating and the post-treatment the initial roughness of the surface of the valve shaft has been reduced significantly. This is astonishing also under the aspect, as the mechanical properties, for example of the MoN layer comprises significantly higher values with respect to hardness and modulus of elasticity (compare table 1), as it is the case for cold work steel as well as for fast work steel. An explanation for it cannot be given.

TABLE 2
Comparison of surface characteristics before and after
the MoN coating (with post-treatment) of valve shafts

| | | Valve shaft |
|---|---|---|
| | Valve shaft | (after post-treatment of |
| Roughness parameter | (before post-treatment) | the MoN coating) |
| Ra [μm] | 0.24 | 0.12 |
| Rz [μm] | 2.07 | 0.98 |
| Rpkx [μm] | 1.33 | 0.31 |

Summarized it can be said that the MoN-based layers can be easily post-treated and that it leads to a significant reduction of the top roughness characteristic values Rpk and Rpkx. Moreover it is possible to reduce the initial substrate roughness through a combination of coating and post-treatment.

After the production and the properties of the MoN-based layers with respect to their ability of post-treatment have been described, the present invention that could be interrelated to this properties in a manner not clear up to now shall be discussed in more detail. With respect to FIG. 7 and FIG. 8 it has already been noted that the SRV test provides somewhat amazing results in the case that both the body and the counter body are coated and under try conditions in the SRV test:
The friction coefficient for MoN has been significantly smaller (0.4 to 0.5) in comparison to the case of the coated body with post-treatment and the uncoated polished counter body (0.5 to 0.6).
The counter body wear has been significantly smaller in comparison to the case of the coated body without post-treatment and the polished uncoated counter body for lubricated conditions.

Especially the latter shows the complex behaviour of the counter body wear with respect to friction coefficient, surface roughness of the partners in the tribological contact and the hardness of the two friction partners. It is also shown that a low friction coefficient is no sufficient condition for a low counter body wear. Friction coefficient and counter body wear must necessarily be optimized for a tribological system.

4. SRV test: Lubricated, coated body and coated counter body, without post-treatment of the coatings

Based on the above discussed results, it has been now of great interest, to carry out the SRV test with a coated body and a coated counter body under lubricated conditions. The progress of the friction coefficients for these tests are shown in FIG. 10. All graphs show a very low noise that can only be compared to the one of graph 1 in FIG. 3. The largest friction coefficient of about 0.2 comprises the CrN coated pairing. MoN and MoCuN can hardly be told apart from one another. This is even true for the running-in. At the end of the test the friction coefficient showed values between 0.16 and 0.17. These friction coefficients are also not larger than the ones from graph 2 in FIG. 3 that is 0.17. However, from the above examinations, one could learn that a low friction coefficient is no guaranty for a low wear, especially not with respect to the counter body wear. The wear examinations are shown in FIG. 2. There is almost no wear for the layers. Only in the case of CrN one can detect stripes, which indicate both a decoration by the lubrication oil as well as scratches from splashes worked out from the layer. The counter body comprises also such stripes with CrN. Remarkable is the fact that despite the larger surface roughness with MoCuN there are no such stripes at the corresponding counter body. Both with MoN as well as with MoCuN no wear can be measured, neither on the layers nor on the counter body. One can only observe a smoothening on both sides whose areas are defined by the deformation through Hertzian pressing. These results show that with a coating of body and counter body and under lubricated conditions a self-smoothening in the MoN-based material occurs, i.e. that neither of the two coatings must be post-treated in order to obtain such ideal conditions as they are shown in graph 1 of FIG. 5.

The current invention is an outstanding solution for the improvement of the tribological behaviour and the reduction of wear of:
Parts of worm gears, planetary gears, differential gears, crank mechanisms, roller gears, wheels gears, screw gears, locking gears such as cog wheels, spur wheels, ball wheels as well as their axles and bearings
Parts of compressors such as pistons, wings, blades, rotary vanes
Parts of ball bearings such as balls, cages, rolls, rollers
Parts of pumps such as pressure bolts, tappets, pistons
Tools such as moulding tools, form- and stamping tools, threading tools, cutting tools
Parts of machine tools such as clamping systems, connecting pieces, guiding rails
Parts of textile machines such as thread guides, spindles, spinning rings, twine holders
Parts of combustion engines and their power transmission systems such as cylinders, pistons, piston bolts, tappets, cup tappets, pot tappets, flat tappets, mushroom tappets, roll tappets, piston rings, piston pumps, connecting rods, connecting rod bearings, radial shaft seals, bearings, sleeves, shafts, crankshafts, crankshaft bearings, camshafts, camshaft bearings, wheel drives, oil pumps, water pumps, injection systems, rocker arms, swing arms, cam followers, housings, turbo charger parts, wings, bolts, valve controls, valve gears, inlet-and outlet valves, bearings of cooling agent pumps, parts of injection pumps
Clockworks and their components
Parts of vacuum pumps such as booster pumps, roots pumps and turbo molecular pumps, in particular bearings
Seals and valves
Parts of turbines such as bearings and rods
Parts of wind generators such as bearings

### LEGEND OF THE FIGURES

FIG. 1: Graphs of the friction coefficients over time under the SRV test conditions A1/B1/C2 for the coating of the body with CrN (1), MoN (2) and MoCuN (3).

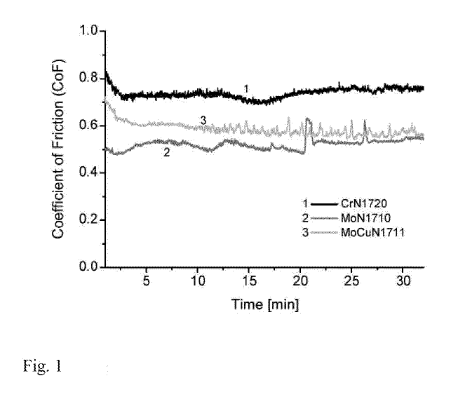

FIG. 2: Light microscopic recordings of the wear traces on the CrN (a), MoN (b) and MoCuN (c) layer (upper row) with the corresponding wear of the uncoated counter body (d-f, lower row) for the test conditions A1/B1/C2.

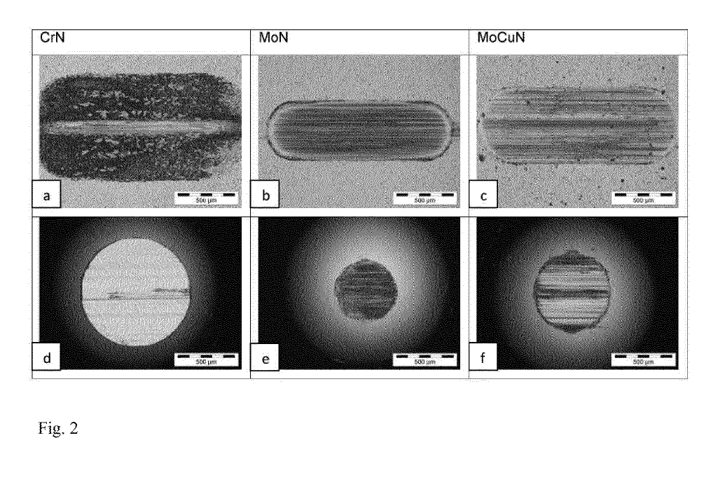

FIG. 3: Graphs of the friction coefficients over time under the SRV test conditions A2/B1/C2 for the coating of the body with CrN (1), MoN (2) and MoCuN (3).

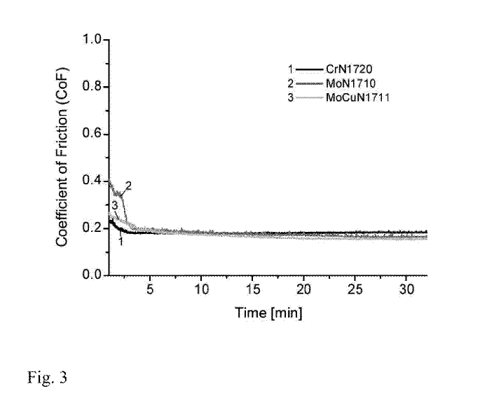

FIG. 4: Light microscopic recordings of the wear traces on the CrN (a), MoN (b) and MoCuN (c) layer (upper row) with the corresponding wear of the uncoated counter body (d-f, lower row) for the test conditions A2/B1/C2.

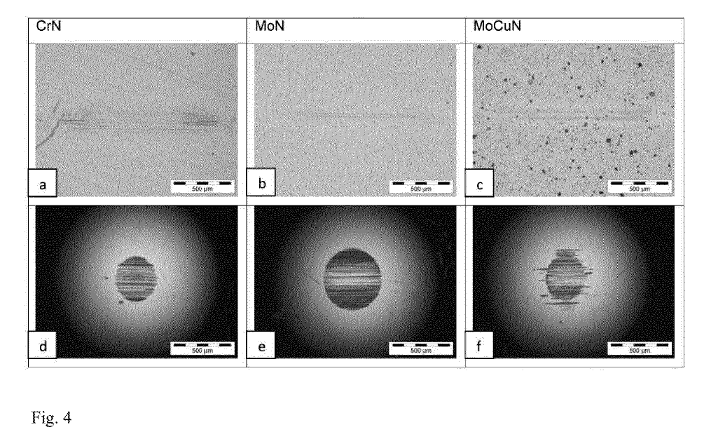

FIG. 5: Graphs of the friction coefficients over time in the case of the MoN coatings for the test conditions A2/B1/C1 (1), A1/B1/C1 (2) and A1/B2/C2.

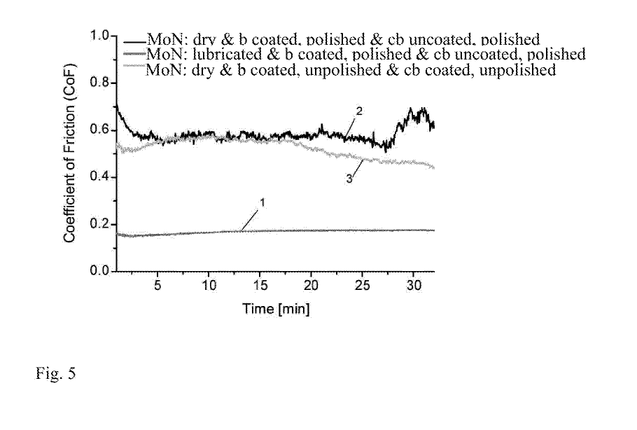

FIG. 6: Comparison of the wear for MoN layers for different conditions in the SRV test. Light microscopic recordings of the wear traces (upper row) and the corresponding wear of the counter body (lower row) for the conditions A2/B1/C1 (a vs d), A1/B1/C1 (b vs e) and A1/B2/C2 (c vs f).

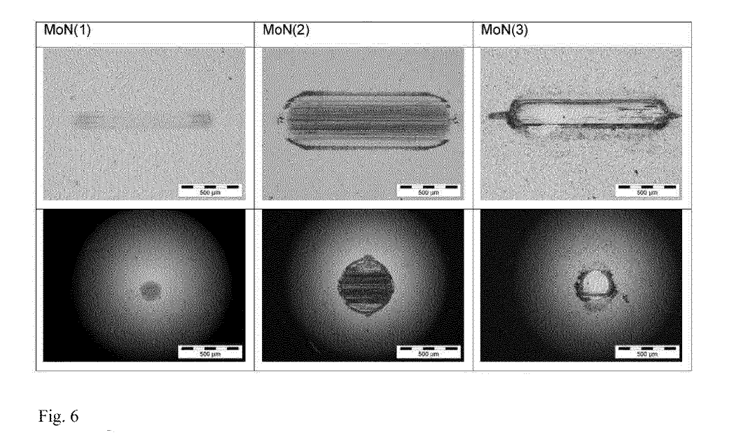

FIG. 7: Graphs of the friction coefficients over time under the SRV test conditions A1/B2/C2 for the coating of the body with CrN (1), MoN (2) and MoCuN (3).

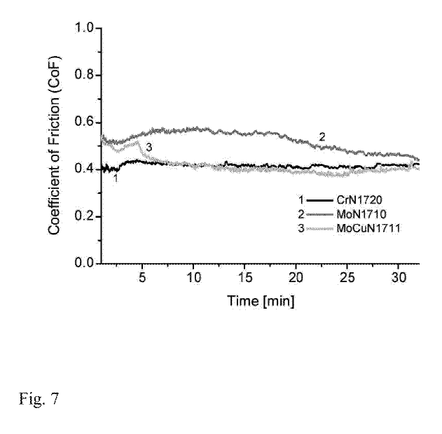

FIG. 8: Light microscopic recordings of the wear trace on the CrN (a), MoN (b) and MoCuN (c) layer (upper row) with the corresponding wear of the counter body, coated with the same layer (d-f, lower row) for the test conditions A1/B2/C2.

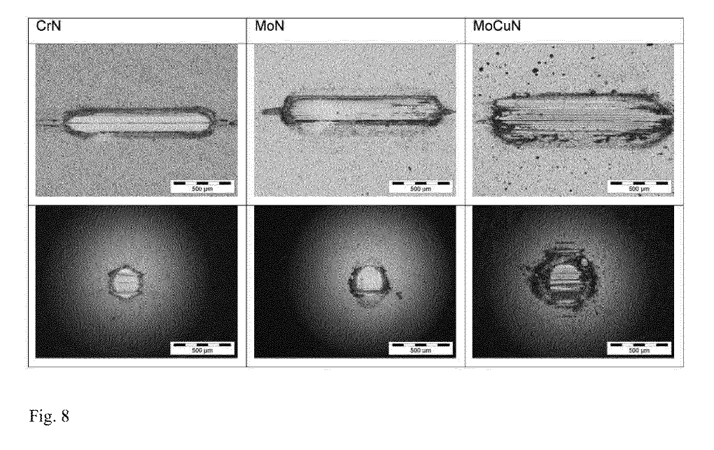

FIG. 9: Comparison of MoN and MoCuN layers before (left) and after (right) the post-treatment. One can see that the post-treatment leads to a significant reduction of the Rpk and Rpkx values. This is also true for the Rvk an Rvkx values. But the reduction of these values is less distinct than for the Rpk and Rpkx values (for the definition of these values see [2]).

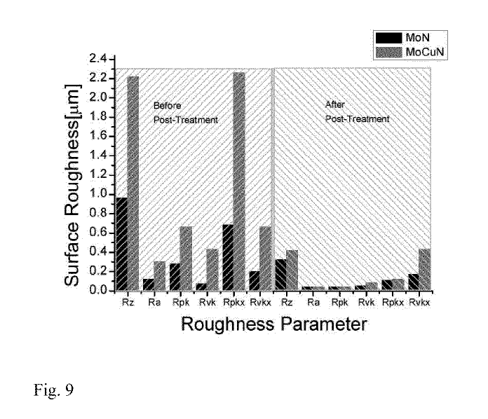

FIG. 10: Graphs of the friction coefficient over time under the SRV test conditions A2/B2/C2 for the coating of the body with CrN (1), MoN (2) and MoCuN (3).

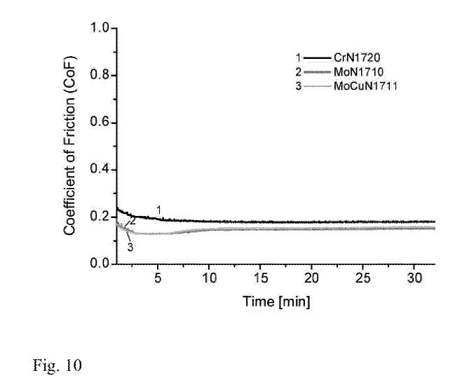

FIG. 11: Light microscopic recordings of the wear trace on the CrN (a), MoN (b) and MoCuN (c) layer (upper row) with the corresponding wear of the uncoated counter body (d-f, lower row) for the test conditions A2/B2/C2.

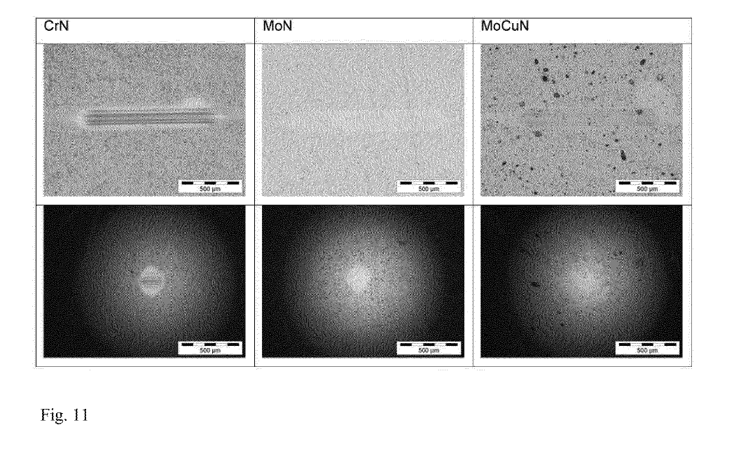

In practice the invention relates to a tribological system, which comprises a body with a first contact face, which is coated at least partially with a first coating, a counter body with a second contact face, which is coated at least partially with a second coating and a lubricant as an interbedding, characterized in that the first and second coating each comprise a layer as an outermost layer, wherein the composition of the outermost layer of the first coating and the composition of the outermost layer of the second coating are selected as such, that
both outermost layers are smearing on steel surfaces when they are exposed to tribological contact with steel, and
both outermost layers are material-related layers, so that the element composition of the fist outermost layer complies to the element composition of the second outermost layer at least to 60 atom percent.

According to a preferred embodiment of the current invention the surface of the outermost layer of the first coating and/or the surface of the outermost layer of the second coating is not post-treated, so that the surface of the outermost layer of the first coating and/or the surface of the outermost layer of the second coating comprises droplets in the beginning of the tribological contact (between the contact faces of the body and the counter body), which smoothen themselves and/or which let themselves be removed through the relative movement of the two contact faces. Such outermost layers with droplets can for example be deposited by means of arc-evaporation. Arc-layers usually have an excellent layer quality, but at the same time have the drawback that they comprise droplets. Therefore such layers must be post-treated before a tribological application in such a way that the droplets are smoothened or removed. However, the droplets according to this preferred embodiment of the current invention are not disadvantageous, but on the contrary are very advantageous, as these droplets contribute to the smoothening of each other, without the production of layer damage or layer flaking.

In tribological systems according to the current invention, the inventors have observed an essentially good tribological behaviour, if the droplets aren't compounded strongly with the layer. The inventors further observed that the roughness values Rpk and Rpkx in these cases of the examined outermost layers have been smaller than the roughness values Rvk and Rvkx after a mechanical post-treatment or after the tribological contact during the operation of the tribological systems.

According to a further preferred embodiment, the outermost layer of the first coating and/or the outermost layer of the second coating comprises molybdenum. Even more preferred the outermost layer of the fist coating and/or the outermost layer of the second coating comprises molybdenum nitride.

As particularly advantageous, the inventors have found that at least one of the molybdenum nitride-comprising layer comprises a dopant element or a combination of dopant elements selected from the elements Cu, Cr, Ti, Zr, Si, O, C, Zr, Nb, Ag, Hf, Ta, W, B, Y, Pt, Au, Pd and V. Preferably, at least in one of the molybdenum nitride-comprising layers, the dopant element is Cu or the combination of dopant elements comprises for the most part Cu.

According to another further preferred embodiment of the current invention the fist and/or the second coating comprises at least one further layer underneath the outermost layer, wherein the lower layer is an oxide layer. This embodiment is especially advantageous if the tribological system is initially set at a low temperature, for example at room temperature, and in the following is operated at higher temperatures. In these cases it may also be that the oxide layers are deposited by means of arc evaporation. The outermost layers can then work as sacrificial layer, so that they initiate the smoothing of the coated contact surfaces. In this way the droplets of the oxide layers are smoothed gently or are removed, without damaging the droplets in the oxide layers or without causing flaking of the coatings.

Preferably the first and the second coating each comprise an oxide layer under the outermost layer, wherein the composition of the two oxide layers is selected as such that the oxide layers are material-related layers, so that the composition of the oxide layer in the first coating complies to the composition of the oxide layer in the second coating to at least 60 atom percent.

Preferably at least the outermost layers of the coatings are deposited by means of arc evaporation. In this way at least the droplets present in the outermost layers are “characteristic by means of arc evaporation produced droplets” and the layers comprise an excellent layer quality with respect to further layer properties.

Preferably also the oxide layers are deposited by means of arc evaporation and therefore comprise “characteristic droplets” and excellent layer quality.

However, the first and second coating can also comprise further lower layers, who for example, can comprise one or more support layers, or one or more undercoatings for increasing the adhesion between the coating and the substrate.

What is claimed is:

1. A tribological system comprising a body with a first contact face, which is coated at least partially with a first coating, a counter body with a second contact face, which is coated at least partially with a second coating and a lubricant as an interbedding, characterized in that the first and second coating each comprise a layer as an outermost layer, wherein the composition of the outermost layer of the first coating and the composition of the outermost layer of the second coating are selected as such, that
both outermost layers are smearing on steel surfaces when they are exposed to a tribological contact with steel, and
both outermost layers are material-related layers, so that the element composition of the fist outermost layer comply to the element composition of the second outermost layer at least to 60 atom percent.

2. Tribological system according to claim 1, characterized in that the surface of the outermost layer of the first coating and/or the surface of the outermost layer of the second coating comprises droplets in the beginning of the tribological contact, which are smoothened and/or let themselves be removed through the relative movement of the two contact faces.

3. Tribological system according to claim 2, characterized in that the droplets aren't bonded strongly with the layer, so that roughness values Rpk and Rpkx are smaller than roughness values Rvk and Rvkx after a mechanical post-treatment or after tribological contact during operation of the tribological systems.

4. Tribological system according to claim 1, characterized in that the outermost layer of the first coating and/or the outermost layer of the second coating comprises molybdenum.

5. Tribological system according to claim 1, characterized in that the outermost layer of the fist coating and/or the outermost layer of the second coating comprises molybdenum nitride.

6. Tribological system according to claim 5, characterized in that at least one of the molybdenum nitride-comprising layer comprises a dopant element or a combination of dopant elements selected from the elements Cu, Cr, Ti, Zr, Si, O, C, Zr, Nb, Ag, Hf, Ta, W, B, Y, Pt, Au, Pd and V.

7. Tribological system according to claim 6, characterized in that at least in one of the molybdenum nitride-comprising layers, the dopant element is Cu or the combination of dopant elements comprises Cu for the most part.

8. Tribological system according to claim 1, characterized in that the fist and/or the second coating comprises at least one further layer underneath the outermost layer, whereby the lower layer is an oxide layer.

9. Tribological system according to claim 8, characterized in that the first and the second coating each comprise an oxide layer under the outermost layer, wherein the composition of the two oxide layers is selected as such that the oxide layers are material-related layers, so that the composition of the oxide layer in the first coating complies to the composition of the oxide layer in the second coating to at least 60 atom percent.

10. Tribological system according to claim 2, characterized in that at least the outermost layers of the coatings have been deposited by means of arc evaporation and therefore the present droplets are characteristic droplets, which have been produced when the arc evaporation process has been performed.

11. Tribological system according to claim 8, characterized in that the oxide layers have been deposited by means of arc evaporation and therefore comprise characteristic droplets.
